(19) United States
(12) Patent Application Publication
(10) Pub. No.: US 2017/0051201 A1
(43) Pub. Date: Feb. 23, 2017

(54) PHOSPHORS

(71) Applicant: Merck Patent GmbH, Darmstadt (DE)

(72) Inventors: Ralf PETRY, Griesheim (DE); Holger WINKLER, Darmstadt (DE); Thomas JUESTEL, Witten (DE); Florian BAUR, Muenster (DE); Kira HEERDT, Steinfurt (DE)

(73) Assignee: Merck Patent GmbH, Darmstadt (DE)

(21) Appl. No.: 15/307,165

(22) PCT Filed: Apr. 1, 2015
(86) PCT No.: PCT/EP2015/000704

§ 371 Date: Oct. 27, 2016

(30) Foreign Application Priority Data
Apr. 28, 2014 (DE) 10 2014 006 003.9

(51) Int. Cl. C09K 11/66; H01L 33/56; H01L 33/32; H01L 33/50

(52) U.S. Cl. CPC C09K 11/666; C09K 11/661; H01L 33/502; H01L 33/56; H01L 33/32; G02F 1/133621

(57) ABSTRACT

The present invention relates to compounds of the formula I,

(A₂₋₂ₙBₙ)ₓ(Ge₁₋ₘMₘ)_{y}O_{(x+2y)}:Mn⁴⁺ I

in which the parameters A, B, M, m, n, x, and y have one of the meanings according to claim 1. Furthermore, the invention relates to a process for the preparation of the compounds of the formula I, to the use of these compounds as conversion phosphors, and to an emission-converting material comprising at least one compound of the formula I. The present invention furthermore relates to a light-emitting device which comprises at least one compound of the formula I according to the invention.

The present invention relates to compounds of the formula I,

(A₂₋₂ₙBₙ)ₓ(Ge₁₋ₘMₘ)_{y}O_{(x+2y)}:Mn⁴⁺ I

in which the parameters A, B, M, m, n, x and y have one of the meanings according to claim 1. Furthermore, the invention relates to a process for the preparation of the compounds of the formula I, to the use of these compounds as conversion phosphors, and to an emission-converting material comprising at least one compound of the formula I. The present invention furthermore relates to a light-emitting device which comprises at least one compound of the formula I according to the invention.

Inorganic fluorescent powders which can be excited in the blue and/or UV spectral region are of major importance as conversion phosphors for phosphor-converted LEDs, pc-LEDs for short. In the meantime, many conversion phosphor systems are known, such as, for example, alkaline-earth metal orthosilicates, thiogallates, garnets, nitrides and oxynitrides, each of which are doped with Ce³⁺ or Eu²⁺. Besides the yellow- or green-emitting garnets or orthosilicates, achievement of warm-white light sources having colour temperatures <4000 K based on blue- or UV-A-emitting (In,Ga)N LEDs requires red-emitting phosphors having emission wavelengths above 600 nm which emit sufficiently strongly at the corresponding wavelength of the primary radiation (370-480 nm).

Most cold-white LEDs that are currently commercially available comprise a colorimetrically optimised Ce³⁺-doped garnet phosphor of the general formula (Y,Gd,Lu,Tb)₃(Al,Ga,Sc)₅O₁₂:Ce.

Warm-white LEDs additionally comprise a second red-emitting phosphor, which is either an Eu²⁺-doped orthosilicate phosphor or an Eu²⁺-doped (oxy)nitride phosphor.

The main disadvantage of the use of an LED light source comprising a broadband-emitting Ce³⁺-doped garnet phosphor and a broadband-emitting Eu²⁺-doped orthosilicate phosphor or (oxy)nitride phosphor in the red spectral region, besides any chemical instability, in particular to moisture, is the pronounced reabsorption and emission of radiation in the NIR region, so that the lumen yield of warm-white LEDs is significantly lower (approx. factor of 2 or more) than that of a corresponding cold-white LED.

Reabsorption in this connection is taken to mean that a certain proportion of the fluorescent light generated in the phosphor cannot leave the phosphor since it is totally reflected at the interface to the optically thinner environment and migrates in the phosphor via wave conduction processes and is finally lost.

Near infrared (NIR) denotes the region of the electromagnetic spectrum which is adjacent to visible light in the direction of longer wavelength. This region of infrared light usually extends from 701 nm to 3 μm.

The phosphors (Ca,Sr)S:Eu, (Ca,Sr)AlSiN₃:Eu and (Ca,Sr,Ba)₂Si₅N₈:Eu used to date are all based on the activator Eu²⁺, which is distinguished both by a broad absorption spectrum and also by a broad emission band. The main disadvantage of these Eu²⁺-activated materials is their relatively high sensitivity with respect to photodegradation, since the divalent Eu²⁺ tends towards photoionisation, in particular in host materials having a relatively small band gap.

A further disadvantage is the fairly high half-value width of the Eu²⁺ emission band, which is evident from a moderate lumen equivalent (<200 lm/W) if the colour point is in the deep-red spectral region. This observation applies, in particular, to the phosphors (Ca,Sr)S:Eu²⁺ and (Ca,Sr)AlSiN₃:Eu²⁺.

Owing to the problems described above, a red narrowband emitter for LEDs whose emission maximum is between 615 and 700 nm is currently being sought. Preference is given here to a narrowband emitter whose emission band is between 630 and 680 nm and has a full width at half maximum of at most 50 nm.

In this connection, the compound SrGe₄O₉:Mn⁴⁺ is proposed, for example, in U.S. Pat. No. 7,846,350.

An advantage of Mn⁴⁺-activated phosphors lies in the basic optical transition [Ar]3d³-[Ar]3d³, which is thus an intraconfiguration transition. The Tanabe-Sugano diagram for Mn⁴⁺ shows that this transition is on the one hand in the red spectral region and is on the other hand optically narrow and thus facilitates red phosphors having high colour saturation and at the same time an acceptable lumen equivalent.

The Tanabe-Sugano diagram is a diagram in which the energy difference E from typically the lowest state is plotted against the crystal field splitting energy (Δ) for all electronic states of a system, both quantities standardised to the Racah parameter. Electrostatic repulsion occurring in multielectron systems can be described in its totality by three linear combinations of Slater electron interaction integrals Fₖ (Coulomb integral, exchange integral, repulsion integral). The abbreviations A, Band C for these linear combinations are called Racah parameters.

The number of curves intersected by a vertical line of a given Δ gives the number of possible transitions and thus the number of expected absorption characteristics. The Tanabe-Sugano diagram is thus a correlation diagram which enables the interpretation of absorption spectra of chemical compounds.

It is thus one of the objects of the present invention to provide suitable red-emitting phosphors which should be activated by Mn⁴⁺ for the above-mentioned reasons, should be excitable effectively in the blue or near-UV wavelength region and should be suitable as radiation converters for corresponding solid-state light sources, such as (In,Ga)N LEDs or OLEDs.

Surprisingly, the inventors have found that compounds of the formula I,

(A₂₋₂ₙBₙ)ₓ(Ge₁₋ₘMₘ)_{y}O_{(x+2y)}:Mn⁴⁺ I

in which
A corresponds to at least one element selected from the group of Li, Na, K and Rb,
B corresponds to (C₁₋ᵤDᵤ),
C corresponds to at least one element selected from the group of Ca, Ba and Sr,
D corresponds to at least one element selected from the group of Ca and Ba,
M corresponds to at least one element selected from the group of Ti, Zr, Hf, Si and Sn,
0≦n≦1, preferably 0 or 1,
0<u≦1, preferably 0.2<u≦ 1, particularly preferably 0.5<u≦1, 0.5≦x≦2,
0≦m<1, and
1≦y≦9,
   meet the above-mentioned requirements.

The compounds according to the invention can usually be excited in the near-UV or blue spectral region, preferably at about 280 to 470 nm, particularly preferably at about 300 to 400 nm, and usually have line emission in the red spectral region from about 600 to 700 nm, preferably from about 620 to 680 nm, with a full width at half maximum (FWHM) of the main emission peak of at most 50 nm, preferably at most 40 nm.

The full width at half maximum (FWHM) is a parameter which is frequently used to describe the width of a peak or function. It is defined in a two-dimensional coordinate system (x, y) by the separation (Δx) between two points on the curve with the same y value at which the function achieves half of its maximum value (yₘₐₓ/2).

In the context of this application, blue light denotes light whose emission maximum is between 400 and 459 nm, cyan light denotes light whose emission maximum is between 460 and 505 nm, green light denotes light whose emission maximum is between 506 and 545 nm, yellow light denotes light whose emission maximum is between 546 and 565 nm, orange light denotes light whose emission maximum is between 566 and 600 nm and red light denotes light whose emission maximum is between 601 and 700 nm. The compound according to the invention is preferably a red-emitting conversion phosphor.

Furthermore, the compounds according to the invention are distinguished by a high photoluminescence quantum yield of greater than 80%, preferably greater than 90%, particularly preferably greater than 95%.

The photoluminescence quantum yield (also called quantum yield or quantum efficiency) describes the ratio between the number of photons emitted and absorbed by a compound.

In addition, the compounds according to the invention have high values for the lumen equivalent (≧250 lm/W) and are furthermore distinguished by very good thermal and chemical stability. Furthermore, the compounds according to the invention are highly suitable for use in white LEDs, colour-on-demand (COD) applications, TV backlighting LEDs and electric lamps, such as, for example, fluorescent lamps, and for improving the efficiency of solar cells.

In a preferred embodiment, the compounds of the formula I are selected from the compounds of the following sub-formulae:

((Sr₁₋ᵤBaᵤ))ₓ(Ge₁₋ₘMₘ)_{y}O_{(x+2y)}:Mn⁴⁺ I′

((Sr₁₋ᵤCaᵤ))ₓ(Ge₁₋ₘMₘ)_{y}O_{(x+2y)}:Mn⁴⁺ I″

in which the parameters M, n, u, x, m and y have one of the meanings indicated under formula I.

An advantage of the compounds I′ according to the invention compared with the known compound SrGe₄O₉:Mn⁴⁺ (cf. U.S. Pat. No. 7,846,350) is offered by the admixing, for example, of a barium source during the preparation according to the invention, where a eutectic forms and thus a lowering of the melting point occurs, which simplifies the synthesis and ensures better crystallinity.

In a further preferred embodiment of the present invention, n is equal to 0.

Compounds of the formula I are preferably selected from the group of the compounds of the formula Ia,

(A₂)ₓ(Ge_{1-m-z}MₘMn_{z})_{y}O_{(x+2y)} Ia

in which
A, M, x, y and m have one of the meanings indicated under formula I, and 0<z≦0.01*y.

Preference is given to compounds of the formula I, and sub-formulae thereof, in which 0≦m<0.8, further preferably in which 0≦m<0.5, furthermore in which 0≦m<0.3.

Further preference is given to compounds of the formula I, and sub-formulae thereof, in which x is equal to 0.5, 0.75, 1, 1.25, 1.5, 1.75 or 2, particularly preferably in which x is equal to 1 or 2, in particular in which x is equal to 1.

Preference is furthermore given to compounds of the formula I, and sub-formulae thereof, in which y corresponds to an integer in the range 1≦y≦9, i.e. 1, 2, 3, 4, 5, 6, 7, 8 or 9, especially preferably in which y is equal to 4.

In a further preferred embodiment, the compounds of the formula I are selected from the group of the compounds of the formulae Ia-1 to Ia-4,

A₂Ge_{1-z}Mn_{z}M₃O₉ Ia-1

A₂Ge_{2-z}Mn_{z}M₂O₉ Ia-2

A₂Ge_{3-z}Mn_{z}MO₉ Ia-3

A₂Ge_{4-z}Mn_{z}O₉ Ia-4

in which
M, z and A have one of the meanings indicated under formula Ia.

Depending on the composition, in particular with respect to the variation of the parameters A, M and m, the emission in the red spectral region can be varied specifically in the range from 600 nm to 700 nm.

In a further embodiment, germanium in the compounds according to the invention is partially replaced by silicon, where M is equal to Si and m>0. Particular preference is given to compounds of the formula I, and sub-formulae thereof, in which M is equal to Si, m>0 and at the same time y is equal to 4, x is equal to 1, and 0.001≦z≦0.004.

In an equally preferred embodiment, compounds of the formula I are selected from the compounds in which m is equal to 0, where at the same time y is equal to 4, x is equal to 1 and 0.001≦z≦0.004.

In an embodiment, A denotes precisely one element selected from the group of Li, Na, K and Rb. However, preference is equally also given to compounds of the formula I, and sub-formulae thereof, in which A corresponds to a mixture of these elements, i.e. at least two elements selected from the group of Li, Na, K and Rb.

The compounds according to the invention are particularly preferably selected from the following sub-formulae:

A₂Ge_{4-z}Mn_{z}O₉,

further preferably,

Li₂Ge_{4-z}Mn_{z}O₉,

K₂Ge_{4-z}Mn_{z}O₉,

Na₂Ge_{4-z}Mn_{z}O₉,

Rb₂Ge_{4-z}Mn_{z}O₉,

A₂SiGe_{3-z}Mn_{z}O₉,

further preferably,

Li₂SiGe_{3-z}Mn_{z}O₉,

K₂SiGe_{3-z}Mn_{z}O₉,

Na₂SiGe_{3-z}Mn_{z}O₉,

Rb₂SiGe_{3-z}Mn_{z}O₉,

A₂Si₂Ge_{2-z}Mn_{z}O₉,

further preferably,

Li₂Si₂Ge_{2-z}Mn_{z}O₉,

K₂Si₂Ge_{2-z}Mn_{z}O₉,

Na₂Si₂Ge_{2-z}Mn_{z}O₉,

Rb₂Si₂Ge_{2-z}Mn_{z}O₉,

and

A₂Si₃Ge_{1-z}Mn_{z}O₉,

further preferably,

Li₂Si₃Ge_{1-z}Mn_{z}O₉,

K₂Si₃Ge_{1-z}Mn_{z}O₉,

Na₂Si₃Ge_{1-z}Mn_{z}O₉,

Rb₂Si₃Ge_{1-z}Mn_{z}O₉,

in which
z has one of the meanings indicated under formula Ia, and particularly preferably z=0.01*y.

Equal preference is given to the above-mentioned compounds in which A denotes at least two elements selected from the group of Li, Na, K and Rb, such as, for example, Na_{1.8}Li_{0.2}Ge_{0.999}Mn_{0.001}Si₃O₉.

The compounds according to the invention can be in the form of phase mixtures or alternatively in phase-pure form. In a preferred embodiment, the compounds according to the invention are in phase-pure form.

An X-ray diffraction pattern enables the phase purity of a crystalline powder to be investigated, i.e. whether the sample consists only of one crystalline compound (phase-pure) or a plurality of compounds (multiphase). In phase-pure powders, all reflections can be observed and assigned to the compound.

The particle size of the compounds according to the invention is usually between 50 μm and 1 μm, preferably between 30 μm and 3 μm, particularly preferably between 20 μm and 5 μm.

The present invention furthermore relates to a process for the preparation of a compound according to the invention, characterised in that suitable starting materials, selected from the group of corresponding oxides, carbonates, oxalates or corresponding reactive forms, are mixed in a step a), and the mixture is thermally treated in a step b).

The process according to the invention is preferably characterised by the following process steps:
(a) preparation of a mixture comprising at least one manganese source; at least one lithium, sodium, potassium, rubidium, calcium, barium and/or strontium source; at least one manganese source, at least one germanium source and optionally a titanium, zirconium, hafnium, silicon and/or tin source;
(b) calcination of the mixture under oxidising conditions.

The manganese source employed in step (a) can be any conceivable manganese compound with which a compound according to the invention can be prepared. The manganese source employed is preferably a carbonate, oxalate and/or oxide, in particular manganese oxalate dihydrate (MnC₂O₄*2H₂O).

The germanium source employed in step (a) can be any conceivable germanium compound with which a compound according to the invention can be prepared. The germanium source employed is preferably an oxide, in particular germanium oxide (GeO₂).

The lithium, sodium, potassium, rubidium, calcium, barium and/or strontium source employed in step (a) can be any conceivable lithium, sodium, potassium, rubidium, calcium, barium and/or strontium compound with which a compound according to the invention can be prepared. The lithium, sodium, potassium, rubidium, calcium, barium and/or strontium compound employed in the process according to the invention is preferably a corresponding carbonate or oxide, in particular lithium carbonate (Li₂CO₃), sodium carbonate (Na₂CO₃), potassium carbonate (K₂CO₃), rubidium carbonate (Rb₂CO₃), calcium carbonate (CaCO₃), barium carbonate (BaCO₃) and/or strontium carbonate (SrCO₃).

The titanium, zirconium, hafnium, silicon and/or tin source employed in step (a) can be any conceivable titanium, zirconium, hafnium, silicon and/or tin compound with which a compound according to the invention can be prepared. The titanium, zirconium, hafnium, silicon and/or tin source employed in the process according to the invention is preferably a corresponding nitride and/or oxide.

The compounds are preferably employed in a ratio to one another such that the number of atoms corresponds to the desired ratio in the product of the above-mentioned formulae. In particular, a stoichiometric ratio is used here.

The starting compounds in step (a) are preferably employed in powder form and processed with one another, for example by means of a mortar, to give a homogeneous mixture. For this purpose, the starting compounds can preferably be suspended in an inert organic solvent known to the person skilled in the art, for example acetone. In this case, the mixture is dried before calcination.

The calcination in step (b) is carried out under oxidising conditions. Oxidising conditions are taken to mean any conceivable oxidising atmospheres, such as, for example, air or other oxygen-containing atmospheres.

The fluxing agent employed can optionally be at least one substance from the group of the ammonium halides, preferably ammonium chloride, alkali metal fluorides, such as sodium fluoride, potassium fluoride or lithium fluoride, alkaline-earth metal fluorides, such as calcium fluoride, strontium fluoride or barium fluoride, carbonates, preferably ammonium hydrogencarbonate, or various alcoholates and/or oxalates.

The calcination is preferably carried out at a temperature in the range from 700° C. to 1200° C., particularly preferably 800° C. to 1000° C. and in particular 850° C. to 950° C. The calcination duration here is preferably 2 to 14 h, more preferably 4 to 12 h and in particular 6 to 10 h.

The calcination is preferably carried out by introducing the mixtures obtained into a high-temperature oven, for example in a boron nitride vessel. The high-temperature oven is, for example, a tubular oven which contains a molybdenum foil tray.

After the calcination, the compounds obtained are optionally homogenised, where a corresponding grinding process can be carried out wet in a suitable solvent, for example in isopropanol, or dry.

The calcined product can optionally be re-calcined under the above-mentioned conditions and with optional addition of a suitable fluxing agent selected from the group of the ammonium halides, preferably ammonium chloride, alkali metal fluorides, such as sodium fluoride, potassium fluoride or lithium fluoride, alkaline-earth metal fluorides, such as calcium fluoride, strontium fluoride or barium fluoride, carbonates, preferably ammonium hydrogencarbonate, or various alcoholates and/or oxalates.

In a further embodiment, the compounds according to the invention can be coated. Suitable for this purpose are all coating methods as are known to the person skilled in the art in accordance with the prior art and are used for phosphors. Suitable materials for the coating are, in particular, metal oxides and metal nitrides, in particular alkaline-earth metal oxides, such as Al₂O₃, and alkaline-earth metal nitrides, such as AlN, as well as SiO₂. The coating here can be carried out, for example, by fluidised-bed methods. Further suitable coating methods are known from JP 04-304290, WO 91/10715, WO 99/27033, US 2007/0298250, WO 2009/065480 and WO 2010/075908. It is also possible to apply an organic coating as an alternative and/or in addition to the above-mentioned inorganic coating. The coating can have an advantageous effect on the stability of the compounds and the dispersibility.

The present invention furthermore relates to the use of the compound according to the invention as phosphor, in particular as conversion phosphor.

The term “conversion phosphor” in the sense of the present application is taken to mean a material which absorbs radiation in a certain wavelength region of the electromagnetic spectrum, preferably in the blue or UV spectral region, and emits visible light in another wavelength region of the electromagnetic spectrum, preferably in the red or orange spectral region, in particular in the red spectral region. The term “radiation-induced emission efficiency” should also be understood in this connection, i.e. the conversion phosphor absorbs radiation in a certain wavelength region and emits radiation with a certain efficiency in another wavelength region. The term “shift of the emission wavelength” is taken to mean that a conversion phosphor emits light at a different wavelength, i.e. shifted to a shorter or longer wavelength, compared with another or similar conversion phosphor. The emission maximum is thus shifted.

The present invention furthermore relates to an emission-converting material comprising one or more compounds of one of the above-mentioned formulae according to the invention. The emission-converting material may consist of one of the compounds according to the invention and would in this case be equivalent to the term “conversion phosphor” defined above.

It is also possible for the emission-converting material according to the invention to comprise further conversion phosphors besides the compound according to the invention. In this case, the emission-converting material according to the invention comprises a mixture of at least two conversion phosphors, where one of these is a compound according to the invention. It is particularly preferred for the at least two conversion phosphors to be phosphors which emit light of different wavelengths which are complementary to one another. Since the compound according to the invention is a red-emitting phosphor, this is preferably employed in combination with a green- or yellow-emitting phosphor or also with a cyan- or blue-emitting phosphor. Alternatively, the red-emitting conversion phosphor according to the invention can also be employed in combination with (a) blue- and green-emitting conversion phosphor(s). Alternatively, the red-emitting conversion phosphor according to the invention can also be employed in combination with (a) green-emitting conversion phosphor(s). It may thus be preferred for the conversion phosphor according to the invention to be employed in the emission-converting material according to the invention in combination with one or more further conversion phosphors, which then together preferably emit white light.

In general, any possible conversion phosphor can be employed as a further conversion phosphor which can be employed together with the compound according to the invention. The following, for example, are suitable here: Ba₂SiO₄:Eu²⁺, BaSi₂O₅:Pb²⁺, BaₓSr₁₋ₓF₂:Eu²⁺, BaSrMgSi₂O₇:Eu²⁺, BaTiP₂O₇, (Ba,Ti)₂P₂O₇:Ti, Ba₃WO₆:U, BaY₂F₈:Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺, Mn²⁺, CaAl₂O₄:Tb³⁺, Ca₃Al₂Si₃O₁₂:Ce³⁺, Ca₃Al₂Si₃Oi₂:Ce³⁺, Ca₃Al₂Si₃O₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO₄)₃Cl:Eu²⁺, CaBr₂:Eu²⁺ in SiO₂, CaC₂:Eu²⁺ in SiO₂, CaC₂:Eu²⁺,Mn²⁺ in SiO₂, CaF₂:Ce³⁺, CaF₂:Ce³⁺,Mn²⁺, CaF₂:Ce³⁺,Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺,Mn²⁺ in SiO₂, CaLaBO₄:Eu³⁺, CaLaB₃O₇:Ce³⁺,Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺,Mn²⁺, Ca₂MgSi₂O₇:Eu²⁺,Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:TI, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺,Mn²⁺, Ca₅(PO₄)₃F:Mn²⁺, Ca₅(PO₄)₃F:Sb³⁺, Caₛ(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺,Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu⁺,Na⁺, CaS:La³⁺, CaS:Mn²⁺, CaSO₄:Bi, CaSO₄:Ce³⁺, CaSO₄:Ce³⁺,Mn²⁺, CaSO₄:Eu²⁺, CaSO₄:Eu²⁺,Mn²⁺, CaSO₄:Pb²⁺, CaS:Pb²⁺, CaS:Pb²⁺,Cl, CaS:Pb²⁺,Mn²⁺, CaS:Pr³⁺, Pb²⁺,Cl, CaS:Sb³⁺, CaS:Sb³⁺,Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺,Pb, CaSiO₃:Pb²⁺, CaSiO₃:Pb²⁺,Mn²⁺, CaSiO₃:Ti⁴⁺, CaSr₂(PO₄)₂:Bi³⁺, β-(Ca,Sr)₃(PO₄)₂:Sn²⁺Mn²⁺, CaTi_{0.9}A_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺,Cr, CdS:In, CdS:In, CdS:In,Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr,Ce, GdNbO₄:Bi³⁺, Gd₂O₂S:Eu³⁺, Gd₂O₂Pr³⁺, Gd₂O₂S:Pr,Ce,F, Gd₂O₂S:Tb³⁺, Gd₂SiO₅:Ce³⁺, KA₁₁O₁₇:TI⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb)PO₄:Ce:Tb, LaCl₃:Ce³⁺, La₂O₃:Bi³⁺, LaOBr:Tb³⁺, LaOBr:Tm³⁺, LaOCI:Bi³⁺, LaOCI:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺,Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺,Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAlₙO₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:TI, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYF₄:Er³⁺, Yb³⁺, NaYO₂:Eu³⁺, P46(70%)+P47 (30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺, Mn²⁺, SrB₈O₁₃:Sm²⁺, Sr_{X}Ba_{y}Cl_{z}Al₂O_{4-z/2}: Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:E²,Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺,Cl, β-SrO.3B₂O₃:Pb²⁺, β-SrO.3B₂O₃:Pb²⁺,Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺, Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)_{3F}:Sn²⁺, Sr₂P₂O₇:Sn²⁺, β-Sr₃(PO₄)2:Sn²⁺, (3-Sr₃(PO₄)₂:Sn²⁺,Mn²⁺(Al), SrS:Ce³⁺, SrS:Eu²⁺, SrS:Mn²⁺, SrS:Cu⁺,Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃:Pr³⁺, SrTiO₃:Pr³⁺,Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺,Cr³⁺, YAl₃B₄O₁₂:Th⁴⁺,Ce³⁺,Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu³⁺, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺,Yb³⁺, YF₃:Mn²⁺, YF₃:Mn²⁺,Th⁴⁺, YF₃:Tm³⁺,Yb³⁺, (Y,Gd)BO₃:Eu, (Y,Gd)BO₃:Tb, (Y,Gd)₂O₃:Eu³⁺, Y_{1.34}Gd_{0.60}O₃(Eu, Pr), Y₂O₃:Bi³⁺, YOBr:Eu³⁺, Y₂O₃:Ce, Y₂O₃:Er³⁺, Y₂O₃:Eu³⁺(YOE), Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S: Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺,Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺,Cl⁻, ZnS:Ag,Cu,Cl, ZnS:Ag,Ni, ZnS:Au,In, ZnS—CdS (25-75), ZnS—CdS (50-50), ZnS—CdS (75-25), ZnS—CdS:Ag,Br,Ni, ZnS—CdS:Ag⁺,Cl, ZnS—CdS:Cu,Br, ZnS—CdS:Cu,I, ZnS:Cl⁻, ZnS:Eu²⁺, ZnS:Cu, ZnS:Cu⁺,Al³⁺, ZnS:Cu⁺,Cl⁻, ZnS:Cu,Sn, ZnS:Eu²⁺, ZnS:Mn²⁺, ZnS:Mn,Cu, ZnS:Mn²⁺,Te²⁺, ZnS:P, ZnS:P³⁻,Cl⁻, ZnS:Pb²⁺, ZnS:Pb²⁺,C⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn,Sb₂O₂, Zn₂SiO₄:Mn²⁺,P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu⁺,Cl or ZnWO₄.

Compounds according to the invention give rise to good LED qualities even when employed in small amounts. The LED quality is described here via conventional parameters, such as, for example, the colour rendering index, the correlated colour temperature, lumen equivalents or absolute lumens, or the colour point in CIE x and CIE y coordinates.

The colour rendering index or CRI is a dimensionless lighting quantity, familiar to the person skilled in the art, which compares the colour reproduction faithfulness of an artificial light source with that of sunlight or filament light sources (the latter two have a CRI of 100).

The CCT or correlated colour temperature is a lighting quantity, familiar to the person skilled in the art, with the unit kelvin. The higher the numerical value, the colder the white light from an artificial radiation source appears to the observer. The CCT follows the concept of the black body radiator, whose colour temperature describes the so-called Planck curve in the CIE diagram.

The lumen equivalent is a lighting quantity, familiar to the person skilled in the art, with the unit lm/W which describes the magnitude of the photometric luminous flux in lumens of a light source at a certain radiometric radiation power with the unit watt. The higher the lumen equivalent, the more efficient a light source.

The lumen is a photometric lighting quantity, familiar to the person skilled in the art, which describes the luminous flux of a light source, which is a measure of the total visible radiation emitted by a radiation source. The greater the luminous flux, the brighter the light source appears to the observer.

CIE x and CIE y stand for the coordinates in the standard CIE colour diagram (here standard observer 1931), familiar to the person skilled in the art, by means of which the colour of a light source is described.

All the quantities mentioned above are calculated from emission spectra of the light source by methods familiar to the person skilled in the art.

In this connection, the present invention furthermore relates to the use of the compounds according to the invention or of the emission-converting material according to the invention described above in a light source.

The light source is particularly preferably an LED, in particular a phosphor-converted LED, pc-LED for short. It is particularly preferred here for the emission-converting material to comprise at least one further conversion phosphor besides the conversion phosphor according to the invention, in particular so that the light source emits white light or light having a certain colour point (colour-on-demand principle). “Colour-on-demand principle” is taken to mean the achievement of light having a certain colour point with a pc-LED using one or more conversion phosphors.

The present invention thus furthermore relates to a light source which comprises a primary light source and the emission-converting material.

Here too, it is particularly preferred for the emission-converting material to comprise at least one further conversion phosphor besides the conversion phosphor according to the invention, so that the light source preferably emits white light or light having a certain colour point.

The light source according to the invention is preferably a pc-LED. A pc-LED generally comprises a primary light source and an emission-converting material. The emission-converting material according to the invention can for this purpose either be dispersed in a resin (for example epoxy or silicone resin) or, given suitable size ratios, arranged directly on the primary light source or alternatively, depending on the application, remote therefrom (the latter arrangement also includes “remote phosphor technology”).

The primary light source can be a semiconductor chip, a luminescent light source, such as ZnO, a so-called TCO (transparent conducting oxide), a ZnSe— or SiC-based arrangement, an arrangement based on an organic light-emitting layer (OLED) or a plasma or discharge source, most preferably a semiconductor chip. If the primary light source is a semiconductor chip, it is preferably a luminescent indium aluminium gallium nitride (InAIGaN), as is known from the prior art. Possible forms of primary light sources of this type are known to the person skilled in the art. Furthermore, lasers are suitable as light source.

For use in light sources, in particular pc-LEDs, the emission-converting material according to the invention can also be converted into any desired outer shapes, such as spherical particles, flakes and structured materials and ceramics. These shapes are summarised under the term “shaped bodies”. The shaped bodies are consequently emission-converting shaped bodies.

The invention furthermore relates to a lighting unit which contains at least one light source according to the invention. Lighting units of this type are employed principally in display devices, in particular liquid-crystal display devices (LC displays) having backlighting. The present invention therefore also relates to a display device of this type.

In the lighting unit according to the invention, the optical coupling between the emission-converting material and the primary light source (in particular semiconductor chips) preferably takes place by means of a light-conducting arrangement. In this way, it is possible for the primary light source to be installed at a central location and for this to be optically coupled to the emission-converting material by means of light-conducting devices, such as, for example, optical fibres. In this way, it is possible to achieve lamps adapted to the lighting wishes which consist of one or more different conversion phosphors, which may be arranged to form a light screen, and an optical waveguide, which is coupled to the primary light source. In this way, it is possible to place a strong primary light source at a location which is favourable for electrical installation and to install lamps comprising emission-converting materials, which are coupled to the optical waveguides, without further electrical cabling, merely by laying optical waveguides at any desired locations.

All variants of the invention described here can be combined with one another so long as the respective embodiments are not mutually exclusive. In particular, it is an obvious operation, on the basis of the teaching of this specification, as part of routine optimisation, precisely to combine various variants described here in order to obtain a specific particularly preferred embodiment.

The parameter ranges indicated in this application, unless indicated otherwise, encompass all rational and integer numerical values including the indicated limit values of the parameter range and error limits thereof. The upper and lower limit values indicated for respective ranges and properties in turn result, in combination with one another, in additional preferred ranges.

Throughout the description and the claims of this application, the words “include” and “comprise” and variations of these words, such as, for example, “including” and “includes” are to be interpreted as “including, but not restricted to” and do not exclude other components. The word “include” also encompasses the term “consisting of”, but is not restricted thereto.

The following examples are intended to illustrate the present invention and show, in particular, the result of such illustrative combinations of the invention variants described. However, they should in no way be regarded as limiting, but instead are intended to stimulate generalisation.

All compounds or components which can be used in the preparations are either known and commercially available or can be synthesised by known methods.

The temperatures indicated are always in ° C. It furthermore goes without saying that, both in the description and also in the examples, the amounts of the components added in the compositions always add up to a total of 100%. Percent data should always be regarded in the given connection.

### EXAMPLES

### a) Na_{1.8}Li_{0.2}Ge_{0.999}Mn_{0.0001}Si₃O₉

0.9539 g (9.000 mmol) of Na₂CO₃, 0.0739 g (1.000 mmol) of Li₂CO₃, 1.0453 g (9.990 mmol) of GeO₂, 1.8025 g (30.000 mmol) of SiO₂ and 0.0018 g (0.010 mmol) of MnC₂O₄.2H₂O are thoroughly triturated with acetone in an agate mortar. The powder is dried, transferred into a covered porcelain crucible and calcined at 600° C. for 1 hour. The calcined powder is thoroughly triturated with acetone in an agate mortar together with 2.5% by weight of NaF and 2.5% by weight of LiF. The dried powder is transferred into a covered porcelain crucible and heated at 800° C. for 4 hours.

### b) K₂Ge_{3.996}Mn_{0.004}O₉

1.3820 g (10.000 mmol) of K₂CO₃, 4.1814 g (39.960 mmol) of GeO₂ and 0.0072 g (0.040 mmol) of MnC₂O₄.2H₂O are thoroughly triturated with acetone in an agate mortar. The powder is dried, transferred into a covered porcelain crucible and calcined at 600° C. for 1 hour. The calcined powder is thoroughly triturated with acetone in an agate mortar together with 5% by weight of KF. The dried powder is transferred into a covered porcelain crucible and heated at 800° C. for 4 hours.

### c) Rb₂Ge_{3.996}Mn_{0.004}O₉

2.3095 g (10.000 mmol) of Rb₂CO₃, 4.1814 g (39.960 mmol) of GeO₂ and 0.0072 g (0.040 mmol) of MnC₂O₄.2H₂O are thoroughly triturated with acetone in an agate mortar. The powder is dried, transferred into a covered porcelain crucible and calcined at 600° C. for 1 hour. The calcined powder is thoroughly triturated with acetone in an agate mortar together with 5% by weight of RbF. The dried powder is transferred into a covered porcelain crucible and heated at 780° C. for 4 hours.

### d) K₂SiGe_{2.997}Mn_{0.003}O₉

1.5202 g (11.000 mmol) of K₂CO₃, 0.6008 g (10.00 mmol) of SiO₂, 3.1360 g (29.970 mmol) of GeO₂ and 0.0054 g (0.030 mmol) of MnC₂O₄.2H₂O are thoroughly triturated with acetone in an agate mortar. The powder is dried, transferred into a covered porcelain crucible and calcined at 850° C. for 4 hours.

### e) Production of a Pc-LED Using a Phosphor of the Composition K₂Ge_{3.996}Mn_{0.004}O₉ Prepared in Accordance with the Invention

4 g of the phosphor having the composition K₂Ge_{3.996}Mn_{0.004}O₉ are weighed out, mixed with 1 g of an optically transparent silicone and subsequently mixed homogeneously in a planetary centrifugal mixer so that the phosphor concentration in the overall material is 80% by weight. The silicone/phosphor mixture obtained in this way is applied to the chip of a blue-emitting semiconductor LED with the aid of an automatic dispenser and cured with supply of heat. The blue LEDs used for the LED characterisation in the present example have an emission wavelength of 442 nm and are operated at a current strength of 350 mA. The photometric characterisation of the LED is carried out using an Instrument Systems CAS 140 spectrometer and an attached ISP 250 integration sphere. The LED is characterised via determination of the wavelength-dependent spectral power density. The resultant spectrum of the light emitted by the LED is used to calculate the colour point coordinates CIE x and y.

### DESCRIPTION OF THE FIGURES

FIG. 1. XRD patterns with the ICCD reference for Cu K-alpha radiation

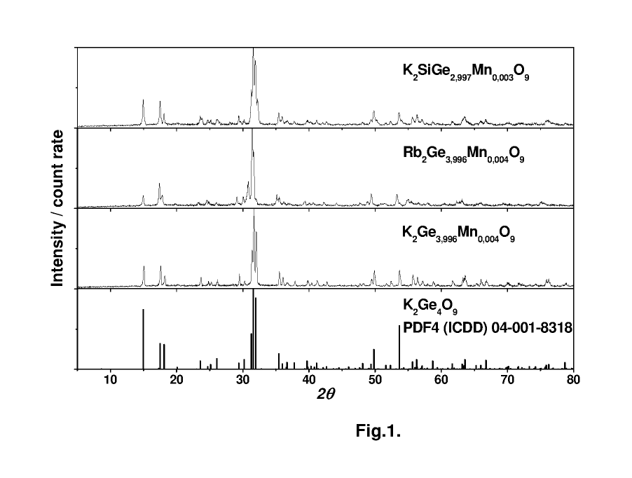

FIG. 2. Reflection spectrum of K₂Ge_{3.996}Mn_{0.004}O₉ against BaSO₄ as white standard.

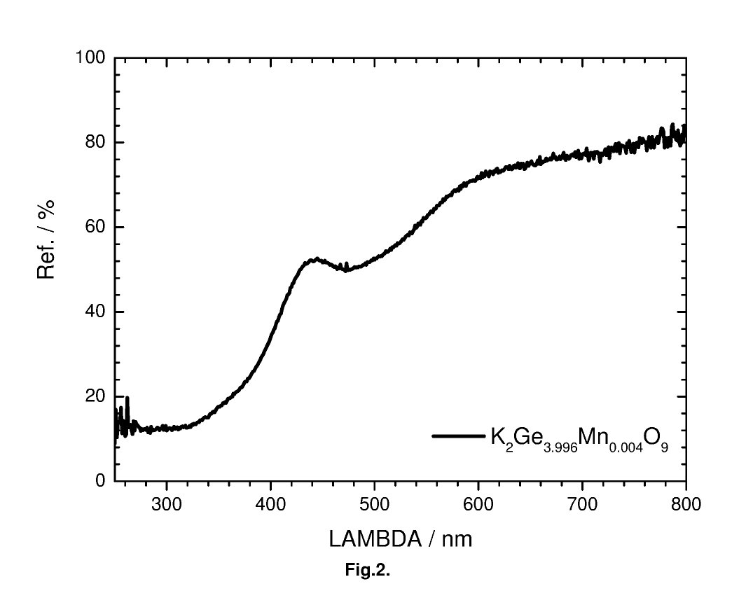

FIG. 3. Reflection spectrum of K₂SiGe_{2.997}Mn_{0.003}O₉ against BaSO₄ as white standard.

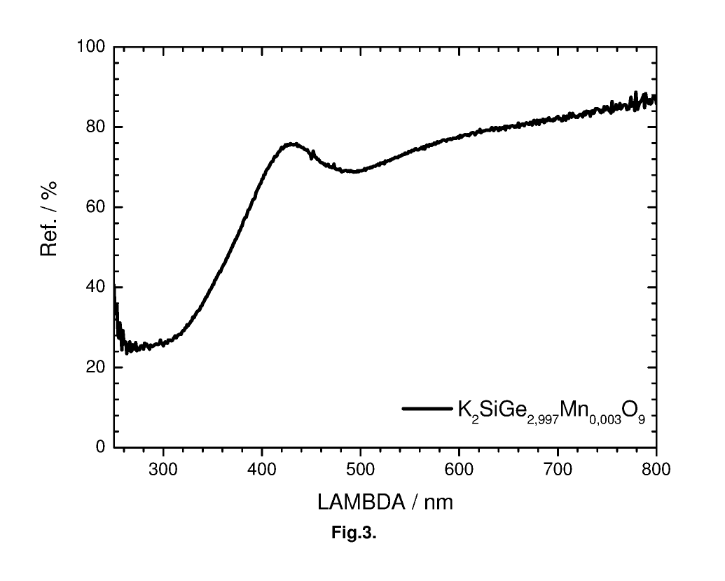

FIG. 4. Reflection spectrum of Rb₂Ge_{3.996}Mn_{0.004}O₉ against BaSO₄ as white standard.

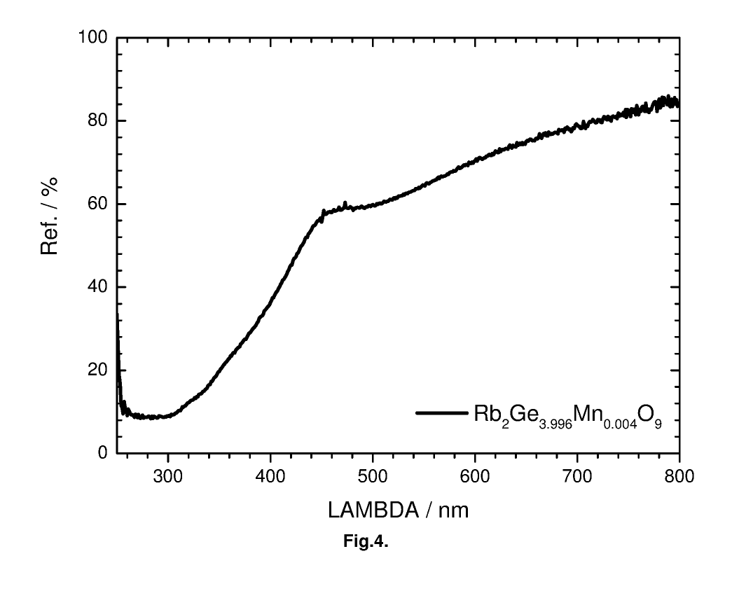

FIG. 5. Excitation spectrum of K₂Ge_{3.996}Mn_{0.004}O₉ (λₑₘ=664 nm)

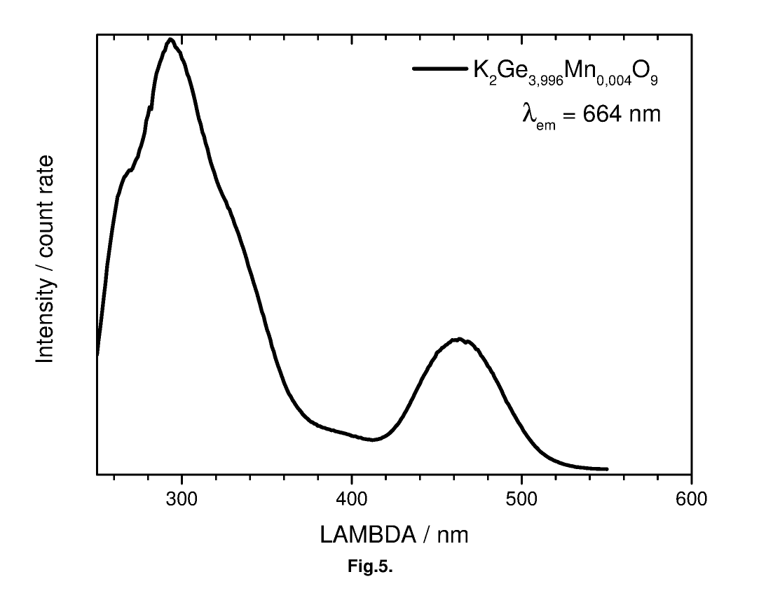

FIG. 6. Excitation spectrum of K₂SiGe_{2.997}Mn_{0.003}O₉ (λₑₘ=664 nm)

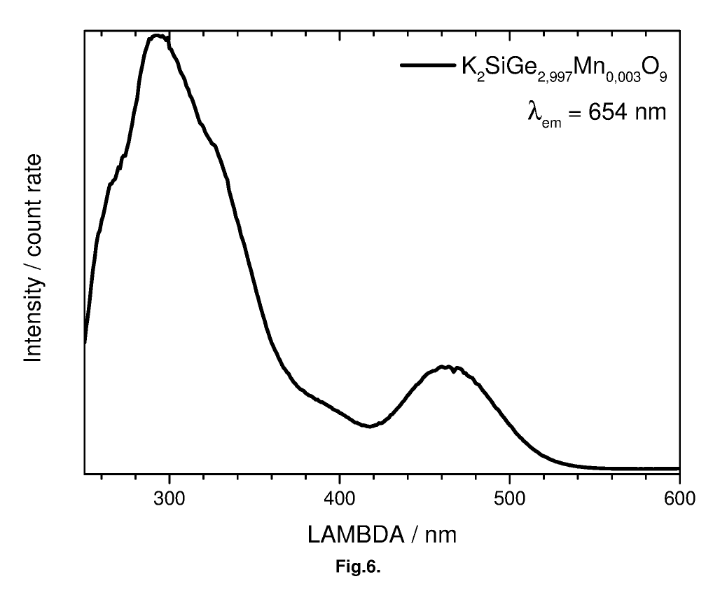

FIG. 7. Excitation spectrum of Rb₂Ge_{3.996}Mn_{0.004}O₉ (λₑₘ=654 nm)

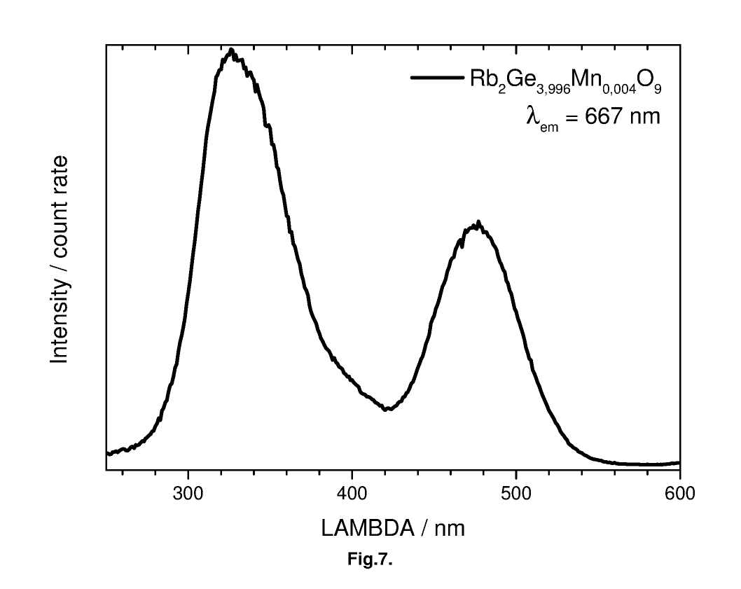

FIG. 8. Emission spectrum of K₂Ge_{3.996}Mn_{0.004}O₉(λₑₓ=320 nm)

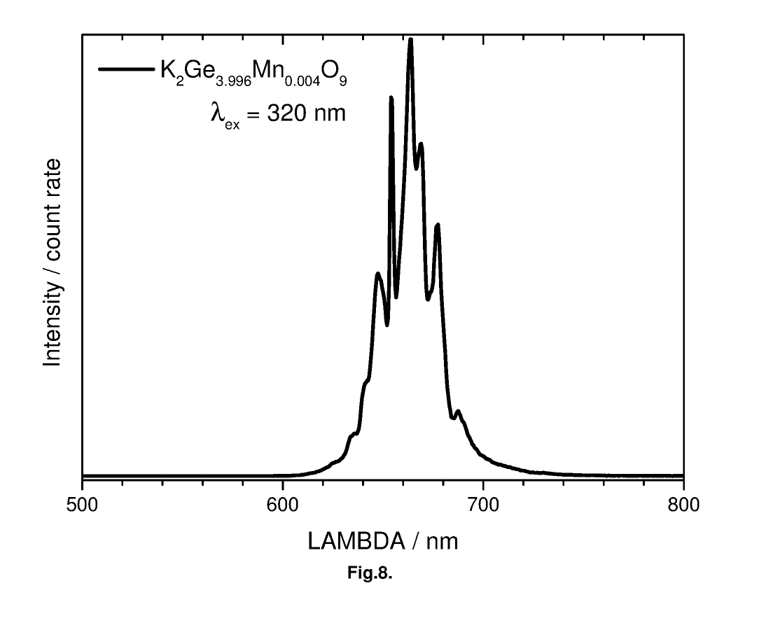

FIG. 9. Emission spectrum of K₂SiGe_{2.997}Mn_{0.003}O₉ (λₑₓ=310 nm)

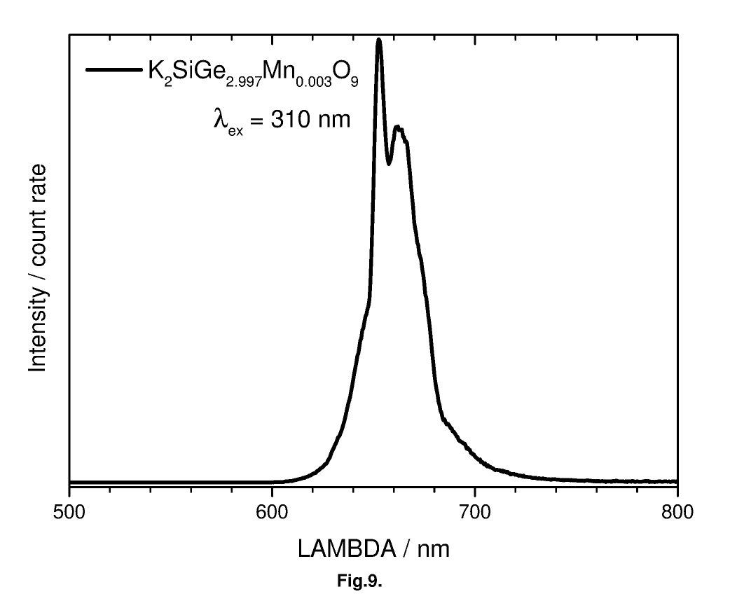

FIG. 10. Emission spectrum of Rb₂Ge_{3.996}Mn_{0.004}O₉ (λₑₓ=327 nm)

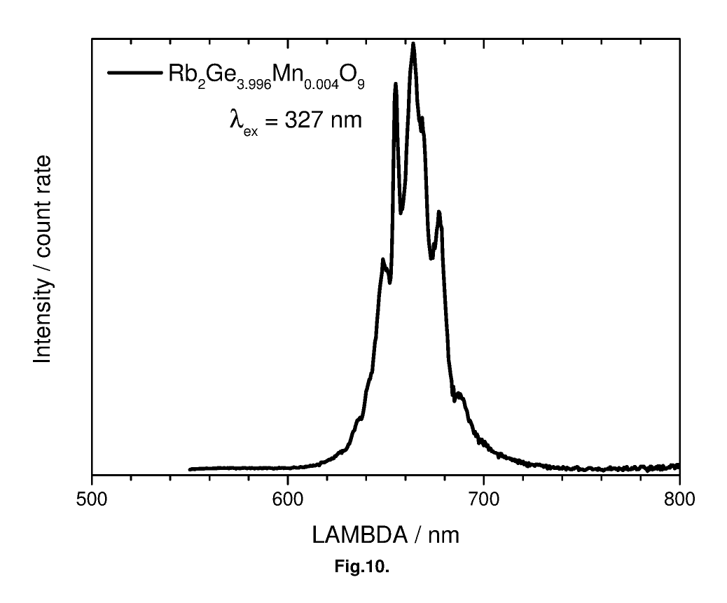

FIG. 11. Section from the CIE 1931 colour diagram with the colour points of K₂Ge_{3.996}Mn_{0.004}O₉, K₂SiGe_{2.997}Mn_{0.003}O₉ and Rb₂Ge_{3.996}Mn_{0.004}O₉.

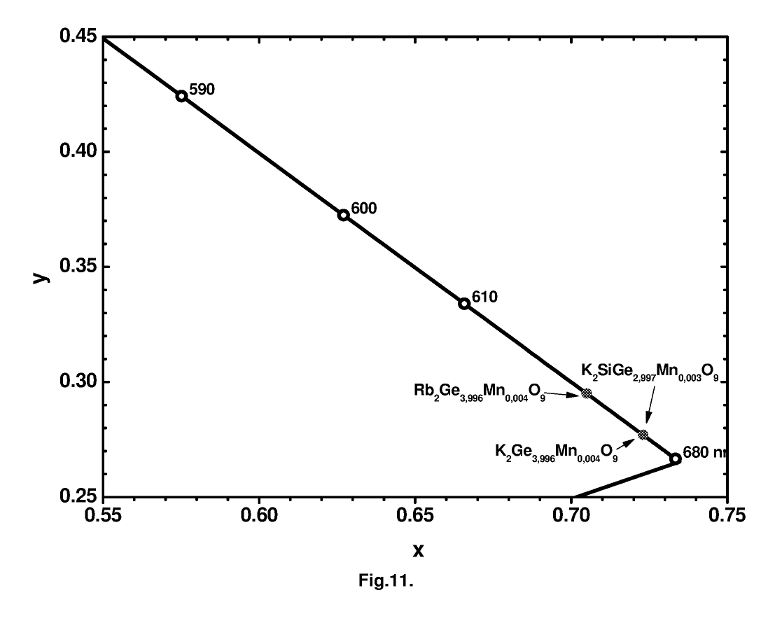

FIG. 12. LED spectrum of the pc-LED described in Example e).

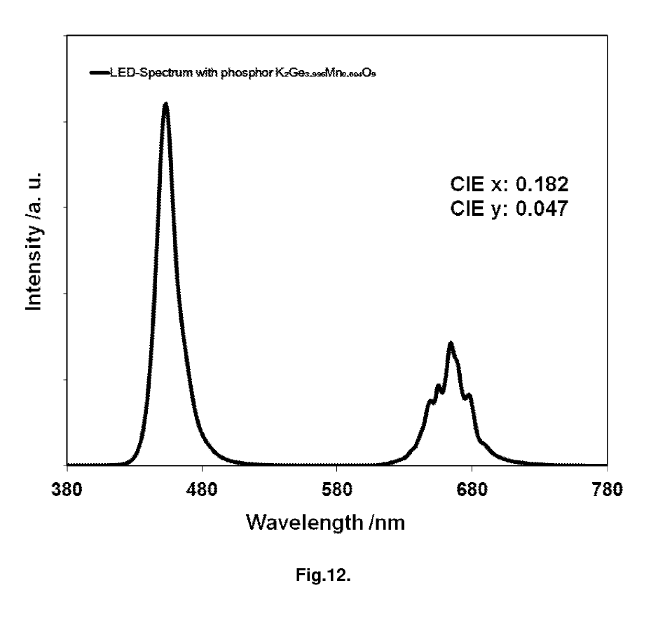

1. Compound of the formula I,
(A₂₋₂ₙBₙ)ₓ(Ge₁₋ₘMₘ)_{y}O_{(x+2y)}:Mn⁴⁺ I
in which
A corresponds to at least one element selected from the group of Li, Na, K and Rb,
B corresponds to (C₁₋ᵤDᵤ),
C corresponds to at least one element selected from the group of Ca, Ba and Sr,
D corresponds to at least one element selected from the group of Ca and Ba,
M corresponds to at least one element selected from the group of Ti, Zr, Hf, Si and Sn,
0≦n≦1,
0<u≦1,
0.5≦x≦2,
0≦m<1, and
1≦y≦9.

2. Compound according to claim 1, characterised in that n is equal to 0.

3. Compound according to claim 1, characterised in that the compound of the formula I is selected from the group of the compounds of the formula Ia,
(A₂)ₓ(Ge_{1-m-z}MₘMn_{z})_{y}O_{(x+2y)} Ia
in which
A, M, x, y and m have one of the meanings indicated under claim 1, and 0<z≦0.01*y.

4. Compound according to claim 1, characterised in that x is equal to 1.

5. Compound according to claim 1, characterised in that y is equal to 4.

6. Compound according to claim 1, characterised in that the compound is selected from the group of the compounds of the formulae Ia-1 to Ia-4,
A₂Ge_{1-z}Mn_{z}M₃O₉ Ia-1
A₂Ge_{2-z}Mn_{z}M₂O₉ Ia-2
A₂Ge_{3-z}Mn_{z}MO₉ Ia-3
A₂Ge_{4-z}Mn_{z}O₉ Ia-4
in which
M, z and A have one of the meanings indicated under claim 1.

7. Compound according to claim 1, characterised in that M is equal to Si.

8. Compound according to claim 1, characterised in that 0.001≦z≦0.004.

9. Compound according to claim 1, characterised in that A corresponds to at least two elements selected from the group of Li, Na, K and Rb.

10. Process for the preparation of a compound according to claim 1, characterised in that suitable starting materials or corresponding reactive forms are mixed in a step a), and the mixture is thermally treated in a step b).

11. Process according to claim 10, in which the starting materials in step a) are selected from the group of corresponding oxides, carbonates and oxalates.

12. A method which comprises partially or completely converting a blue or near-UV emission into visible light of a longer wavelength using a compound according to claim 1.

13. Emission-converting material comprising at least one compound according to claim 1 and one or more further conversion phosphors.

14. Light source having at least one primary light source, characterised in that the light source comprises at least one compound according to claim 1.

15. Light source according to claim 14, in which the primary light source corresponds to a luminescent indium aluminium gallium nitride and/or indium gallium nitride.

16. Lighting unit, in particular for the backlighting of display devices, characterised in that it contains at least one light source according to claim 14.

17. Display device, in particular liquid-crystal display device (LC display), having backlighting, characterised in that it contains at least one lighting unit according to claim 16.
